(19) United States
(12) Patent Application Publication
(10) Pub. No.: US 2013/0264565 A1
(43) Pub. Date: Oct. 10, 2013

(54) SEMICONDUCTOR THIN FILM, THIN FILM TRANSISTOR AND PRODUCTION METHOD THEREFOR

(71) Applicants: Mami Nishimura, Sodegaura-shi (JP); Emi Kawashima, Sodegaura-shi (JP); Masashi Kasami, Sodegaura-shi (JP); Masahide Matsuura, Sodegaura-shi (JP); Masayuki Itose, Sodegaura-shi (JP)

(72) Inventors: Mami Nishimura, Sodegaura-shi (JP); Emi Kawashima, Sodegaura-shi (JP); Masashi Kasami, Sodegaura-shi (JP); Masahide Matsuura, Sodegaura-shi (JP); Masayuki Itose, Sodegaura-shi (JP)

(73) Assignee: IDEMITSU KOSAN CO., LTD.

(21) Appl. No.: 13/878,937

(22) PCT Filed: Oct. 11, 2011
(86) PCT No.: PCT/JP2011/005679

§ 371 Date: Jun. 24, 2013

(30) Foreign Application Priority Data
Oct. 12, 2010 (JP) 2010-229809
Sep. 26, 2011 (JP) 2011-209521

(51) Int. Cl. H01L 29/24; H01L 29/66; H01L 29/786

(52) U.S. Cl. CPC H01L 29/247; H01L 29/78606; H01L 29/66969
USPC 257/43; 438/104

(57) ABSTRACT

A semiconductor thin film includes one or more amorphous metal oxides, an OH group being bonded to at least some of the metal atoms of the amorphous metal oxides.

### TECHNICAL FIELD

The invention relates to a semiconductor thin film, a thin film transistor, and methods for producing the same.

### BACKGROUND ART

A field effect transistor has been widely used as a unit electronic device of a semiconductor memory integrated circuit, a high-frequency signal amplifier device, a liquid crystal drive device, and the like. It is considered that the field effect transistor is an electronic device that is most widely put to practical use at present.

A thin film transistor (TFT) has been widely used for a display (e.g., liquid crystal display (LCD), electroluminescence (EL) display, or field emission display (FED)) as a switching device which drives a display by applying a drive voltage to the display element.

A silicon semiconductor thin film is most widely used as a TFT drive element. On the other hand, a transparent semiconductor thin film formed of a metal oxide that exhibits high mobility and excellent stability has attracted attention.

In recent years, a thin film transistor that utilizes a conductive oxide semiconductor as the channel has been used as a drive transistor for an organic EL panel or a liquid crystal panel.

However, such a thin film transistor is sensitive to the atmosphere, and may change in characteristics due to the atmosphere during operation or storage. This is because an oxide semiconductor that contains ZnO as a main component (see Patent Document 1, for example), or an oxide semiconductor that contains In-M-Zn—O (wherein M is at least one of Ga, Al, and Fe) as the main component, which are generally used, easily undergoes adsorption and desorption due to water, other gas molecules, and the like contained in the atmosphere.

In order to deal with the above problem, Patent Document 2 proposes to cover the channel layer with a protective film.

Such a thin film transistor may show a deterioration in TFT characteristics due to oxygen deficiencies (oxygen defects) caused by the production process (e.g., CVD). In such a case, it is necessary to perform a heat treatment in air or an oxygen-containing atmosphere.

However, when the protective film that covers the channel layer does not allow oxygen to pass through (e.g., a film that contains SiNₓ or a metal) (see Patent Document 2), oxygen may not be diffused into the channel layer, and the TFT characteristics may not be recovered even if the heat treatment is performed.

In contrast, when the protective film that covers the channel layer allows oxygen to pass through (e.g., a film that contains SiO₂), oxygen is diffused into the channel layer, and the TFT characteristics can be recovered. However, since SiO₂ has low density as compared with SiNₓ, a change in TFT characteristics may occur due to the atmosphere during operation.

In order to protect the channel layer while implementing the recovery of the TFT characteristics, a technique that sequentially stacks an oxygen permeable film (e.g., SiO₂) and an oxygen non-permeable film (e.g., a film that contains SiNₓ or a metal) on the channel layer has been proposed (see Patent Document 3, for example). However, such a technique results in a complex process, and an increase in cost.

Patent Document 4 discloses IGZO (amorphous metal oxide) as a material for forming an oxide semiconductor film, and discloses silicon nitride (SiNₓ) as a material for forming a protective film. Patent Document 4 also discloses a drawing in which a protective film is formed on an oxide semiconductor film.

However, Patent Document 4 does not disclose a specific example of the stacked layer structure of IGZO and SiNₓ, and a specific method for forming a semiconductor layer. When SiNₓ is stacked after forming an IGZO channel layer by a normal method, IGZO may be reduced, and lose its semiconductor properties.

### RELATED-ART DOCUMENT

### Patent Document

Patent Document 1: JP-A-2002-76356
Patent Document 2: JP-A-2007-73705
Patent Document 3: JP-A-2010-73894
Patent Document 4: JP-A-2009-260378

### SUMMARY OF THE INVENTION

An object of the invention is to provide a semiconductor thin film that exhibits excellent reduction resistance, and a method for producing the same.

Another object of the invention is to provide a thin film transistor that exhibits stable TFT characteristics even if a buffer layer (e.g., oxygen permeable film) is not provided on a channel layer, and a method for producing the same.

Several aspects of the invention provide the following semiconductor thin film, thin film transistor, and the like.

1. A semiconductor thin film including one or more amorphous metal oxides, an OH group being bonded to at least some of metal atoms of the one or more amorphous metal oxides.
2. The semiconductor thin film according to 1, including one or more metals selected from In and Zn.
3. The semiconductor thin film according to 2, including at least In.
4. The semiconductor thin film according to 2, including In and Zn.
5. The semiconductor thin film according to 2, including In, Zn, and a third element, the third element being at least one or more metal elements selected from Sn, Ga, Hf, Zr, Ti, Al, Mg, Ge, Sm, Nd, and La.
6. The semiconductor thin film according to 5, wherein the third element is Sn.
7. The semiconductor thin film according to 6, including In, Sn, and Zn so that the following expressions are satisfied,

0.2<[In]/([In]+[Sn]+[Zn])<0.8

0<[Sn]/([In]+[Sn]+[Zn])<0.2

0.2<[Zn]/[In]+[Sn]+[Zn])<0.8

where, [In] is the number of indium atoms in the thin film, [Sn] is the number of tin atoms in the thin film, and [Zn] is the number of zinc atoms in the thin film.
8. The semiconductor thin film according to 5, wherein the third element is Ga.
9. The semiconductor thin film according to 8, including In, Ga, and Zn that the following expressions are satisfied,

0.5≦[In]/([In]+[Ga])<1

0.2≦[Zn]/[In]+[Ga]+[Zn])≦0.8

where, [In] is the number of indium atoms in the thin film, [Ga] is the number of gallium atoms in the thin film, and [Zn] is the number of zinc atoms in the thin film.
10. The semiconductor thin film according to 5, wherein the third element is Hf.
11. The semiconductor thin film according to 10, including In, Hf, and Zn so that the following expressions are satisfied,

0.3<[In]/([In]+[Hf]+[Zn])<0.8

0.01<[Hf]/([In]+[Hf]+[Zn])<0.1

0.1<[Zn]/[In]+[Hf]+[Zn])<0.69

where, [In] is the number of indium atoms in the thin film, [Hf] is the number of hafnium atoms in the thin film, and [Zn] is the number of zinc atoms in the thin film.
12. The semiconductor thin film according to 5, wherein the third element is Zr.
13. The semiconductor thin film according to 12, including In, Zr, and Zn that the following expressions are satisfied,

0.3<[In]/([In]+[Zr]+[Zn])<0.8

0.01<[Zr]/([In]+[Zr]+[Zn])<0.1

0.1<[Zn]/([In]+[Zr]+[Zn])<0.69

where, [In] is the number of indium atoms in the thin film, [Zr] is the number of zirconium atoms in the thin film, and [Zn] is the number of zinc atoms in the thin film.
14. A method for producing a semiconductor thin film including any of the following steps (1a) to (1c):
(1a) sputtering a target that includes a metal oxide in a noble gas atmosphere containing water,
(1b) sputtering a target that includes a metal oxide in a gas atmosphere that comprises at least noble gas atoms, oxygen atoms, and hydrogen atoms, and
(1c) sputtering a target that includes a metal oxide to form a semiconductor thin film, and annealing the semiconductor thin film in a water vapor atmosphere.
15. A thin film transistor sequentially including:

a gate electrode;

a channel layer that includes the semiconductor film according to any of 1 to 13; and

a protective film that includes at least SiNₓ,

the protective film being in contact with to the channel layer.

16. A method for producing a thin film transistor including:

forming a channel layer by any of the following steps (1a) to (1c):

(1a) sputtering a target that includes a metal oxide in a noble gas atmosphere containing water,
(1b) sputtering a target that includes a metal oxide in a gas atmosphere that comprises at least noble gas atoms, oxygen atoms, and hydrogen atoms, and
(1c) sputtering a target that includes a metal oxide to form a channel layer, and annealing the channel layer in a water vapor atmosphere;

forming a conductor layer that includes one or more metals selected from the group consisting of Ti, Al, Mo, Cu, and Au, or an oxide thereof, so that the conductor layer is in contact with the channel layer;

patterning the conductor layer to form a source electrode and a drain electrode; and

forming a protecting layer that includes SiNₓ on the source electrode, the drain electrode, and the channel layer.

17. The method for producing a thin film transistor according to 16, wherein the conductor layer includes one or more metals selected from the group consisting of Ti, Al, Mo, Cu, and Au, or an oxide thereof.

The aspects of the invention thus provide a semiconductor thin film that exhibits excellent reduction resistance, and a method for producing the same.

The aspects of the invention thus also provide a thin film transistor that exhibits stable TFT characteristics even if a buffer layer (e.g., oxygen permeable film) is not provided on a channel layer, and a method for producing the same.

### BRIEF DESCRIPTION OF DRAWINGS

FIG. 1 is a view illustrating one embodiment of the invention.

FIG. 2 is a view showing the FT-IR measurement results obtained in Examples 1 and 4 and Comparative Example 1.

FIG. 3 is a view showing the TPD measurement results obtained in Examples 1 and 4 and Comparative Example 1.

### DESCRIPTION OF EMBODIMENTS

### 1. Semiconductor Thin Film

A first semiconductor thin film according to the invention includes one or more amorphous metal oxides, an OH group being bonded to at least some of metal atoms of the one or more amorphous metal oxides.

A state in which an OH group is bonded to a metal atom may be confirmed by Fourier transform infrared spectroscopy (FT-IR) or temperature programmed desorption.

In the semiconductor thin film according to the invention, an OH group is bonded to some or all of the metal atoms of the one or more amorphous metal oxides. A state in which an OH group is bonded to some or all of the metal atoms may be confirmed by FT-IR or the like.

More specifically, when the semiconductor thin film is subjected to Fourier transform infrared spectroscopy (FT-IR measurement), a peak (preferably a peak or a shoulder having a height equal to or larger than 5% (or 10%) of the maximum peak height) is observed at around 1100 cm⁻¹ (1000 to 1300 cm⁻¹) and around 3000 cm⁻¹ (2600 to 3500 cm⁻¹) when an OH group is bonded to some or all of the metal atoms.

When the semiconductor thin film is subjected to temperature programmed desorption (TPD measurement), a peak equal to or larger than 5.0×10¹⁰ (more preferably 8.0×10⁻¹⁰) is preferably observed at 350 to 600° C. when an OH group is bonded to some or all of the metal atoms.

Note that Fourier transform infrared spectroscopy (FT-IR measurement) and temperature programmed desorption (TPD measurement) may be performed by the methods described in connection with the examples.

The expression “semiconductor” used herein refers to a state in which the carrier concentration of the thin film is less than 1×10¹⁹/cm³. The term “carrier concentration” used herein refers to a value measured using a Hall measurement system “ResiTest 8300” (manufactured by Toyo Corporation).

The thin film includes one or more amorphous metal oxides. It is preferable that the thin film substantially include only one or more amorphous metal oxides. The expression “substantially” means that the thin film may include unavoidable impurities as long as the advantageous effects of the invention are not impaired.

When the thin film includes an amorphous oxide, the thin film exhibits excellent uniformity over a large area, and may suitably be used for a peripheral circuit (e.g., system-on-glass (SOG)) or a switching device that drives an organic EL display by an electric current.

Note that the term “amorphous oxide” used herein refers to an oxide for which a clear peak is not observed by X-ray diffraction analysis.

The thin film preferably includes an oxide of one or more metals selected from the group consisting of In and Zn. The thin film more preferably includes at least In, and still more preferably includes In and Zn.

The indium content in all elements in the thin film preferably satisfies the following expression.

0.2≦[In]/total metal atoms≦0.8

where, [In] is the number of indium atoms included in thin film, and “total metal atoms” is the total number of metal atoms included in thin film.

It is more preferable that “0.25≦[In]/total metal atoms≦0.75”, and still more preferable that “0.3≦[In]/total metal atoms≦0.7”.

If the atomic ratio “[In]/total metal atoms” is less than 0.2, the thin film may have a carrier concentration lower than that in the semiconductor region (i.e., the thin film may function as an insulator).

If the atomic ratio “[In]/total metal atoms” exceeds 0.8, the thin film may be easily crystallized, and in-plane electrical properties may be non-uniform when forming the thin film to have a large area.

It is preferable that the thin film include a third element in addition to In and Zn. The third element may be at least one or more metal elements selected from Sn, Ga, Hf, Zr, Ti, Al, Mg, Ge, Sm, Nd, and La.

When the thin film includes Sn as the third element, the thin film exhibits improved chemical resistance. Therefore, it is unnecessary to provide an etch stopper when forming a TFT in a stacked manner using a channel-etch technique. Since Sn functions as a sintering aid when producing a sputtering target, it is possible to easily produce a low-density sputtering target. Moreover, a change in field-effect mobility with respect to a change in water partial pressure is small as compared with the case where the thin film includes Ga as the third element.

When the thin film includes Ga, Hf, Zr, Ti, Al, Ge, Sm, Nd, or La as the third element, it is expected that the carrier concentration can be reduced to a level appropriate for a semiconductor. Since the thin film exhibits chemical resistance to a specific etchant, it is unnecessary to provide an etch stopper by appropriately selecting an etchant. Moreover, it is unnecessary to provide an etch stopper when using a dry etching technique or a lift-off technique.

The third element is preferably Sn. In this case, the thin film preferably includes In, Sn, and Zn so that the following expressions are satisfied.

0.2<[In]/([In]+[Sn]+[Zn])<0.8

0<[Sn]/([In]+[Sn]+[Zn])<0.2

0.2<[Zn]/([In]+[Sn]+[Zn])<0.8

where, [In] is the number of indium atoms in the thin film, [Sn] is the number of tin atoms in the thin film, and [Zn] is the number of zinc atoms in the thin film.

It is more preferable that the following expressions be satisfied.

0.2<[In]/([In]+[Sn]+[Zn])<0.6

0<[Sn]/([In]+[Sn]+[Zn])<0.15

0.4<[Zn]/[In]+[Sn]+[Zn])<0.8

If the atomic ratio “[Sn]/([In]+[Sn]+[Zn])” is 0.2 or more, the thin film according to the invention may be insoluble in an etchant when used to produce a TFT, and it may be difficult to pattern the channel layer. Moreover, the resistance of the sputtering target used when forming the thin film may increase, and it may be difficult to implement DC sputtering.

If the atomic ratio “[In]/([In]+[Sn]+[Zn])” is equal to or less than 0.2, the thin film may have too low a carrier concentration, and may not function as a semiconductor. If the atomic ratio “[In]/([In]+[Sn]+[Zn])” is equal to or larger than 0.8, the carrier density may increase, and the semiconductor properties may be impaired.

It is also preferable that the third element be Ga. In this case, the thin film preferably includes In, Ga, and Zn so that the following expressions are satisfied.

0.5≦[In]/([In]+[Ga])<1

0.2≦[Zn]/([In]+[Ga]+[Zn])≦0.8

where, [In] is the number of indium atoms in the thin film, [Ga] is the number of gallium atoms in the thin film, and [Zn] is the number of zinc atoms in the thin film.

It is more preferable that the following expressions be satisfied.

0.5≦[In]/([In]+[Ga])<1

0.2≦[Zn]/([In]+[Ga]+[Zn])≦0.5

If the atomic ratio “[In]/([In]+[Ga])” is less than 0.5 (or 0.3), the mobility of the TFT element obtained using the thin film according to the invention may decrease.

If the atomic ratio “[Zn]/([In]+[Ga]+[Zn])” is less than 0.2 or exceeds 0.8, the thin film may be easily crystallized, and in-plane electrical properties may be non-uniform when forming the thin film to have a large area.

It is also preferable that the third element be Hf. In this case, the thin film preferably includes In, Hf, and Zn so that the following expressions are satisfied.

0.3<[In]/([In]+[Hf]+[Zn])<0.8

0.01<[Hf]/([In]+[Hf]+[Zn])<0.1

0.1<[Zn]/([In]+[Hf]+[Zn])<0.69

where, [In] is the number of indium atoms in the thin film, [Hf] is the number of hafnium atoms in the thin film, and [Zn] is the number of zinc atoms in the thin film.

It is also preferable that the third element be Zr. In this case, the thin film preferably includes In, Zr, and Zn so that the following expressions are satisfied.

0.3<[In]/([In]+[Zr]+[Zn])<0.8

0.01<[Zr]/([In]+[Zr]+[Zn])<0.1

0.1<[Zn]/[In]+[Zr]+[Zn])<0.69

where, [In] is the number of indium atoms in the thin film, [Zr] is the number of zirconium atoms in the thin film, and [Zn] is the number of zinc atoms in the thin film.

In this case, the thin film more preferably includes Sn in addition to In, Zr, and Zn in order to densify the sputtering target used for sputtering. More specifically, it is preferable that the thin film include so that the following expression is satisfied.

0.1<[Sn]/([In]+[Zr]+[Zn]+[Sn])<0.2

When the third element is Zr or Hf, the thermal stability, the heat resistance, and the chemical resistance of the thin film are improved, and the S-value and the Off-state current can be reduced. Moreover, the photocurrent can be reduced.

Since the semiconductor thin film is formed in an atmosphere that contains water or oxygen atoms and hydrogen atoms (described later), and exhibits vacuum resistance and reduction resistance, oxygen defects (deficiencies) rarely occur during the production process (e.g., CVD), and a deterioration in TFT characteristics does not occur when used in a TFT. This makes it unnecessary to provide a buffer layer (e.g., oxygen permeable film) that takes part in recovery of the TFT characteristics, and makes it possible to produce a TFT using a simple process.

The semiconductor thin film may be produced by a method similar to a method ((1a) to (1c)) for producing a channel layer of a thin film transistor described later.

Oxygen defects in the semiconductor thin film can be effectively suppressed by utilizing the method (1a), (1b), or (1c), so that a stable metal-oxygen bond can be formed. This makes it possible to suppress an increase in carrier concentration of the thin film even if the thin film is subjected to a reducing atmosphere.

Moreover, a semiconductor thin film produced by utilizing the method (1a), (1b), or (1c) has a wide band gap as compared with a semiconductor thin film produced by sputtering a target that is formed of a metal oxide in an oxygen-noble gas atmosphere. Therefore, high reliability can be obtained even when applying light.

A second semiconductor thin film according to the invention is a film produced by the method (1a), (1b), or (1c).

The second semiconductor thin film includes an amorphous metal oxide. The metal oxide preferably has an elemental composition similar to that of the metal oxide included in the first semiconductor thin film.

### 2. Thin Film Transistor

A thin film transistor according to the invention normally includes a gate electrode, a gate insulating film, a channel layer, a source electrode, a drain electrode, and a protective film.

The thin film transistor according to the invention does not require a buffer layer, and allows the protective film to be formed directly on the channel layer. This makes it possible to simplify the production process.

The channel layer includes an amorphous metal oxide. The metal oxide preferably has an elemental composition similar to that of the metal oxide included in the first semiconductor thin film. The first semiconductor thin film or the second semiconductor thin film may be used as the channel layer.

A film that includes at least SiNₓ (silicon nitride) may preferably be used as the protective film. SiNₓ can form a dense film as compared with SiO₂, and can suppress deterioration in TFT characteristics.

The protective film may include an oxide such as SiO₂, SiNₓ, Al₂O₃, Ta₂O₅, TiO₂, MgO, ZrO₂, CeO₂, K₂O, Li₂O, Na₂O, Rb₂O, Sc₂O₃, Y₂O₃, Hf₂O₃, CaHfO₃, PbTi₃, BaTa₂O₆, SrTiO₃, or AlN, in addition to SiNₓ. It is preferable that the protective film substantially include only SiNₓ.

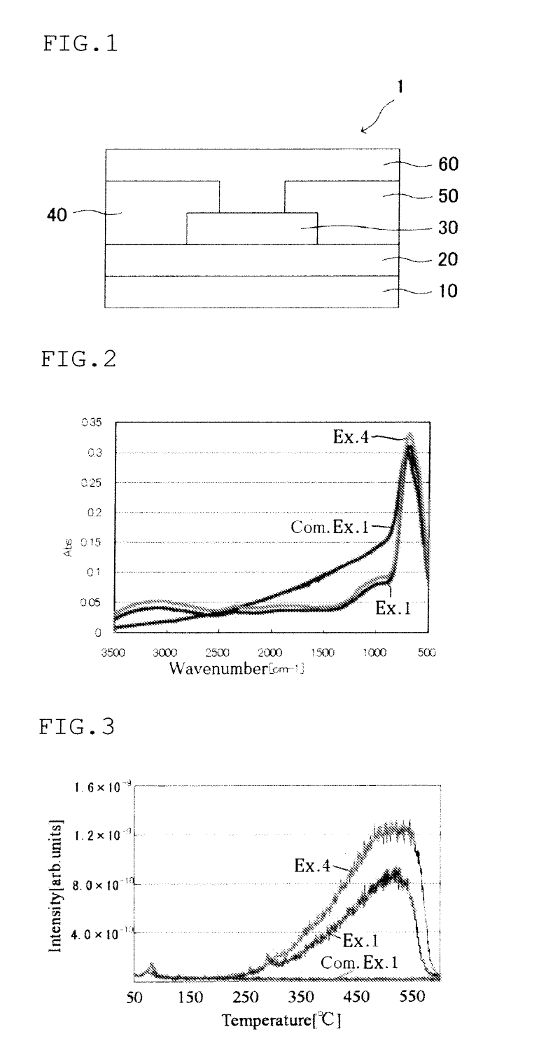

FIG. 1 illustrates a thin film transistor according to one embodiment of the invention.

A thin film transistor 1 illustrated in FIG. 1 includes a gate electrode (substrate) 10, an insulating layer 20 that is formed on the gate electrode 10, a channel layer 30 that is formed on the insulating layer 20, a source electrode 40, and a drain electrode 50, the source electrode 40 and the drain electrode 50 being formed at an interval on the insulating layer 20. The channel layer 30 is formed between the source electrode 40 and the drain electrode 50.

The substrate 10 serves as the gate electrode. The thin film transistor 1 is turned ON/OFF by controlling a current that flows through the channel layer 30 formed between the source electrode 40 and the drain electrode 50 by applying an appropriate voltage to the substrate 10.

A protective film 60 is provided to cover the channel layer 30, the source electrode 40, and the drain electrode 50.

A material for forming each electrode (i.e., drain electrode, source electrode, and gate electrode) is not particularly limited. A commonly-used material may be arbitrarily selected as the material for forming each electrode. For example, a transparent electrode material (e.g., ITO, IZO, ZnO, or SnO₂), a metal electrode material (e.g., Al, Ag, Cu, Cr, Ni, Mo, Au, Ti, or Ta), or an alloy thereof may be used as the material for forming each electrode.

Each electrode (i.e., drain electrode, source electrode, and gate electrode) may have a multilayer structure in which two or more different conductive layers are stacked. The source electrode and the drain electrode may have a structure in which a good conductor (e.g., Al or Cu) is sandwiched between metals that exhibit excellent adhesion (e.g., Ti or Mo) since a reduction in resistance is desired.

A material for forming the gate insulating film is not particularly limited. A commonly-used material may be arbitrarily selected as the material for forming the gate insulating film.

For example, a compound such as SiO₂, SiNₓ, Al₂O₃, Ta₂O₅, TiO₂, MgO, ZrO₂, CeO₂, K₂O, Li₂O, Na₂O, Rb₂O, Sc₂O₃, Y₂O₃, HfO₃, CaHfO₃, PbTi₃, BaTa₂O₆, SrTiO₃, or AlN may be used as the material for forming the gate insulating film. Among these, it is preferable to use SiO₂, SiNₓ, Al₂O₃, Y₂O₃, HfO₃, or CaHfO₃, and more preferably SiO₂, SiNₓ, Y₂O₃, HfO₃, or CaHfO₃.

Note that the number of oxygen atoms of these oxides need not necessarily coincide with the stoichiometric ratio (e.g., SiO₂ or SiOₓ may be used).

The gate insulating film may have a structure in which two or more different insulating films are stacked. The gate insulating film may be crystalline, polycrystalline, or amorphous. It is preferable that the gate insulating film be polycrystalline or amorphous from the viewpoint of ease of industrial production.

The channel layer may be formed by any of the methods (1a) to (1c) described later.

An arbitrary sputtering technique may be used in the methods (1a) to (1c). For example, DC sputtering with low plasma activity, or radio-frequency sputtering at a frequency of 10 MHz or less may be used. Note that pulse sputtering may also be used.

The term “DC sputtering” used herein refers to a sputtering method that is implemented by applying DC power. The term “radio-frequency sputtering (RF sputtering)” used herein refers to a sputtering method that is implemented by applying AC power (AC sputtering). The term “pulse sputtering” used herein refers to a sputtering method that is implemented by applying a pulse voltage.

Since RF sputtering can increase the plasma density, and decrease the discharge voltage as compared with DC sputtering, it is possible to reduce lattice defect and the like, and increase the carrier mobility. It is normally easy to obtain a film that exhibits excellent in-plane uniformity by utilizing RF sputtering.

Therefore, it is expected that a film obtained by RF sputtering exhibits higher field-effect mobility when producing a TFT. However, since the deposition rate achieved by RF sputtering is normally lower than that achieved by DC sputtering, DC sputtering is generally employed on an industrial scale.

The power density applied to the target when forming a film by sputtering is preferably 1 to 5 W/cm², and more preferably 2 to 5 W/cm². The power density is particularly preferably 2.5 to 5 W/cm².

If the power density is less than 1 W/cm², productivity may deteriorate due to a decrease in deposition rate. If the power density exceeds 5 W/cm², it may be difficult to control the thickness of the film due to too high a deposition rate.

The deposition rate (in the direction perpendicular to the surface of the substrate on which the film is formed) during sputtering is normally 1 to 200 nm/min, preferably 1 to 100 nm/min, more preferably 10 to 80 nm/min, and particularly preferably 30 to 60 nm/min.

If the deposition rate is less than 1 nm/min, productivity may deteriorate due to a low deposition rate. If the deposition rate exceeds 200 nm/min, it may be difficult to control the thickness of the film due to too high a deposition rate.

The distance between the target and the substrate (in the direction perpendicular to the surface of the substrate on which the film is formed) is preferably 1 to 15 cm, and more preferably 4 to 8 cm.

If the distance between the target and the substrate is less than 1 cm, the kinetic energy of the particles of the constituent elements of the target that reach the substrate may increase, and a film having excellent properties may not be obtained. Moreover, an in-plane distribution of the thickness and the electrical properties may occur. If the distance between the target and the substrate exceeds 15 cm, the kinetic energy of the particles of the constituent elements of the target that reach the substrate may decrease to a large extent, and a dense film may not be obtained (i.e., excellent film properties may not be obtained).

It is desirable to perform sputtering in an atmosphere having a magnetic field intensity of 300 to 1000 G.

If the magnetic field intensity is less than 300 G, it may be impossible to form a film by sputtering due to a decrease in plasma density when using a high-resistance sputtering target. If the magnetic field intensity is exceeds 1000 G, it may be difficult to control the thickness and the electrical properties of the film.

The pressure of the gas atmosphere (sputtering pressure) is not particularly limited as long as plasma can be stably discharged, but is preferably 0.1 to 5.0 Pa.

Note that the term “sputtering pressure” used herein refers to the total pressure in the system when starting sputtering after introducing argon, oxygen, and the like into the system.

A method for producing a thin film transistor according to the invention includes (1a) sputtering a target that includes a metal oxide in a noble gas atmosphere containing water to form a channel layer that includes an amorphous metal oxide, (2) forming a conductor layer that includes at least one or more metals selected from the group consisting of Ti, Al, Mo, Cu, and Au, or an oxide thereof, so that the conductor layer is adjacent to the channel layer, wherein the conductor layer preferably consists of at least one or more metals selected from the group consisting of Ti, Al, Mo, Cu, and Au, or an oxide thereof, (3) patterning the conductor layer to form a source electrode and a drain electrode, and (4) forming a protective film that includes SiNₓ on the source electrode, the drain electrode, and the channel layer.

It is possible to effectively suppress oxygen defects in the channel layer by utilizing the step (1a), so that a stable metal-oxygen bond can be formed. This makes it possible to suppress an increase in carrier concentration of the thin film even if the thin film is subjected to a reducing atmosphere.

The partial pressure ratio of the water molecules to the rare gas atoms is represented by [H₂O]/([H₂O]+[rare gas atom]). Note that [H₂O] is the partial pressure of the water molecules in the gas atmosphere, and [rare gas atom] is the partial pressure of the rare gas atoms in the gas atmosphere. The partial pressure ratio is preferably 0.1 to 10%, more preferably 0.5 to 7.0%, still more preferably 1.0 to 5.0%, and particularly preferably 1.0 to 3.0%.

If the partial pressure ratio of the water molecules to the rare gas atoms is less than 0.1%, oxygen defects (deficiencies) may not be suppressed, and the carrier concentration in the film may decrease. If the partial pressure ratio of the water molecules to the rare gas atoms exceeds 10%, the mobility of the resulting TFT may decrease.

Note that the rare gas atom is not particularly limited, but is preferably an argon atom. The atmosphere may contain oxygen and nitrogen in addition to the noble gas and water as long as the resulting TFT is not adversely affected.

The channel layer may be formed by (1b) sputtering a target that includes a metal oxide in a noble gas atmosphere that contains oxygen atoms and hydrogen atoms to form a channel layer that includes an amorphous metal oxide, instead of using the step (1a).

When using the step (1b), it is preferable that the gas atmosphere during sputtering contain hydrogen atoms in an amount (molar ratio) equal to or larger than twice that of oxygen atoms. This makes it possible to achieve an effect similar to that achieved when introducing water into the gas atmosphere.

In the steps (1a) and (1b), the resulting channel layer is preferably annealed at 200 to 400° C. for 5 to 120 minutes. The stability of the semiconductor properties of the resulting oxide semiconductor can be improved by annealing the channel layer, and deterioration due to the subsequent process can be suppressed.

If the annealing temperature is less than 200° C., or the annealing time is less than 5 minutes, it may be difficult to achieve the above effects. If the annealing temperature exceeds 400° C., or the annealing time exceeds 120 minutes, crystallization may occur.

The above-mentioned annealing is not affected by the atmosphere as long as the annealing temperature is 200 to 400° C. It is preferable to perform annealing in an atmosphere that contains at least oxygen. It is possible to suppress a variation in characteristics of a TFT produced using the annealed thin film by performing annealing in an atmosphere that contains oxygen.

The channel layer may be formed by step (1c) sputtering a target that includes a metal oxide to form a channel layer, and annealing the channel layer in a high-pressure water vapor atmosphere, instead of using the step (1a).

In this case, the channel layer is annealed at a temperature of 200 to 400° C. and a pressure of 1 to 3 MPa for 5 to 120 minutes using a high-pressure water vapor annealing furnace.

The thickness of the channel layer is appropriately selected depending on the specific resistance of the channel layer. It is preferable that the channel layer have a large thickness from the viewpoint of uniformity. It is preferable that the channel layer have a small thickness from the viewpoint of the deposition time (takt time).

The thickness of the channel layer is normally 20 to 500 nm, preferably 40 to 150 nm, more preferably 50 to 140 nm, still more preferably 60 to 130 nm, and particularly preferably 70 to 110 nm.

If the thickness of the channel layer is less than 20 nm, the TFT characteristics may be non-uniform due to non-uniformity in thickness when forming the channel layer to have a large area. If the thickness of the channel layer exceeds 500 nm, it may take time to form the channel layer (i.e., industrial application may be difficult).

The thin film transistor according to the invention has a high field-effect mobility and a high ON/OFF ratio, is normally off, and shows a clear pinch-off phenomenon.

The thin film transistor according to the invention can be formed on a substrate that has a limited heat resistant (e.g., non-alkali glass) since the metal oxide can be formed at a low temperature.

The channel layer according to the invention is normally used as an N-type region, and may be used for various semiconductor devices (e.g., PN-junction transistor) in combination with a P-type semiconductor (e.g., P-type Si semiconductor, P-type oxide semiconductor, or P-type organic semiconductor).

The thin film transistor according to the invention may be used as a field effect transistor, and may also be applied to an integrated circuit (e.g., logic circuit, memory circuit, or differential amplifier circuit). The thin film transistor according to the invention may also be used as a static induction transistor, a Schottky barrier transistor, a Schottky diode, and a resistor element.

The thin film transistor according to the invention may have an arbitrary known configuration (e.g., bottom gate configuration, bottom contact configuration, or top contact configuration).

It is advantageous that the thin film transistor have a bottom gate configuration since high performance can be achieved as compared with an amorphous silicon or ZnO thin film transistor. Moreover, since the number of masks used during the production process can be reduced, the production cost can be reduced (e.g., when producing a large display).

It is preferable that the thin film transistor be a channel-etch thin film transistor having a bottom gate configuration when used for a large display. When using a channel-etch thin film transistor having a bottom gate configuration, a display panel can be produced at low cost since the number of photomasks used during photolithography can be reduced. It is particularly preferable that the thin film transistor be a channel-etch thin film transistor having a bottom gate-top contact configuration from the viewpoint of an increase in mobility and the like, and ease of industrial production.

The field-effect mobility of the thin film transistor is normally 1 cm²/Vs or more, preferably 5 cm²/Vs or more, more preferably 18 cm²/Vs or more, still more preferably 30 cm²/Vs or more, and particularly preferably 50 cm²/Vs or more.

If the field-effect mobility of the thin film transistor is less than 1 cm²/Vs, the switching speed may decrease.

The ON/OFF ratio of the thin film transistor is normally 10³ or more, preferably 10⁴ or more, more preferably 10⁵ or more, still more preferably 10⁶ or more, and particularly preferably 10⁷ or more.

It is preferable that the thin film transistor be normally-off when the threshold voltage (Vth) is positive from the viewpoint of power consumption. Power consumption may increase if the thin film transistor is normally-on when the threshold voltage (Vth) is negative.

### EXAMPLES

### Example 1

### (1) Production of Thin Film Transistor

A conductive silicon substrate on which a thermal oxide film (thickness: 100 nm) was formed, was used as a substrate. The thermal oxide film functions as a gate insulating film, and the conductive silicon functions as a gate electrode.

A film was formed by sputtering on the gate insulating film under the conditions shown in Table 1 using an In₂O₃—SnO₂—ZnO (ITZO) target. A resist (“OFPR #800” manufactured by Tokyo Ohka Kogyo Co., Ltd.) was applied to the resulting film, prebaked (80° C., 5 min), and exposed. The resist was then developed, post-baked (120° C., 5 min), and etched using oxalic acid to pattern the resist into the desired shape. The film was annealed at 300° C. for 1 hour in a hot-blast heating furnace.

A halo pattern was observed (i.e., a clear peak was not observed) when subjecting the resulting film to X-ray diffraction (XRD) analysis. Therefore, it was determined that the film was amorphous.

An Mo film (thickness: 200 nm) was then formed by sputtering. A source/drain electrode having the desired shape was patterned by a channel-etch technique. An SiNₓ film (protecting film) was then formed by plasma-enhanced CVD (PECVD). A contact hole was formed using hydrofluoric acid to obtain a thin film transistor.

### (2) Evaluation

The ON current, the OFF current, the field-effect mobility (p), the S-value, and the threshold voltage (Vth) of the thin film transistor were evaluated. The ON current, the OFF current, the field-effect mobility (μ), the S-value, and the threshold voltage (Vth) were measured at room temperature in a shading environment (in a shield box) using a semiconductor parameter analyzer (“4200SCS” manufactured by Keithley Instruments Inc.). The drain voltage (Vd) was set to 10 V. The results are shown in Table 1.

### (3) Evaluation of Single-Layer Oxide Semiconductor Film

### (3-1) Measurement of Band Gap

An oxide thin film was formed by sputtering on a quartz substrate under the conditions shown in Table 1 using an In₂O₃—SnO₂—ZnO (ITZO) target shown in table 1. The thin film was annealed at 300° C. for 1 hour.

The band gap of the thin film was measured as described below.

The values Ψ and Δ were measured using a variable angle spectroscopic ellipsometer (manufactured by J.A. Woollam Japan Co., Inc.) (incident angle: 50 to 70°, wavelength region: 192.3 to 1689 nm). A fitting process was performed using the T-L model, the Gaussian model, and the Drude model on the assumption that the thin film is uniform to determine the extinction coefficient k and the refractive index n. The absorption coefficient α was calculated from the extinction coefficient k and the refractive index n, and the band gap was read on the assumption that the thin film is a direct transition semiconductor. The results are shown in Table 1.

### (3-2) FT-IR Measurement

An oxide thin film (thickness: 200 nm) was formed by sputtering on a glass substrate (on which a gold film (thickness: 50 nm) was formed) under the conditions shown in Table 1 using the ITZO target shown in Table 1. The thin film was annealed at 300° C. for 1 hour.

The IR measurement was performed by the attenuated total reflection (ATR) method (single reflection, crystal Ge, incident angle: 45°) using an FT-IR measurement system (manufactured by Bio-Rad) (number of scans: 100). The results are shown in FIG. 2. As shown in FIG. 2, a peak was observed at around 1100 cm⁻¹ and around 3000 cm⁻¹ as a result of the FT-IR measurement.

### (3-3) Temperature Programmed Desorption (TPD) Measurement

An oxide thin film (thickness: 100 nm) was formed by sputtering on an Si wafer under the conditions shown in Table 1 using the ITZO target shown in Table 1. The thin film was annealed at 300° C. for 1 hour.

The TPD measurement was performed at a temperature of 50 to 600° C. and a temperature increase rate of 30° C./min using a TDS-MS analyzer (manufactured by ESCO, Ltd.). The results are shown in FIG. 3.

FIG. 3 shows the resulting TPD spectrum (m/z=18). As shown in FIG. 3, the OH groups bonded to the metal were desorbed as H₂O at 350° C. or higher (Examples 1 and 4). It was thus confirmed that that an OH group was bonded to the metal atoms of the oxide thin films of Example 1 and 4.

### Example 2

A thin film transistor was produced and evaluated in the same manner as in Example 1, except that the channel layer was formed using an In₂O₃—Ga₂O₃—ZnO (IGZO) target, and the source/drain electrode was formed using Ti (50 nm)/Au (100 nm)/Ti (50 nm), and patterned by a lift-off technique. The results are shown in Table 1.

A single-layer film was formed in the same manner as in Example 1, except that the target was changed as shown in Table 1, and subjected to the band gap measurement and the FT-IR measurement in the same manner as in Example 1. A peak was observed at around 1100 cm⁻¹ and around 3000 cm⁻¹ as a result of the FT-IR measurement.

### Example 3

A thin film transistor was produced and evaluated in the same manner as in Example 1, except that the channel layer was formed using an In₂O₃—SnO₂—ZnO—ZrO₂ (ITZZO) target. The results are shown in Table 1.

A single-layer film was formed in the same manner as in Example 1, except that the target was changed as shown in Table 1, and subjected to the band gap measurement and the FT-IR measurement in the same manner as in Example 1. A peak was observed at around 1100 cm⁻¹ and around 3000 cm⁻¹ as a result of the FT-IR measurement.

### Example 4

A thin film transistor was produced and evaluated in the same manner as in Example 1, except that the channel layer sputtering conditions were changed as shown in Table 1. The results are shown in Table 1.

A single-layer film was formed in the same manner as in Example 1, except that the target and the sputtering conditions were changed as shown in Table 1, and subjected to the band gap measurement, the FT-IR measurement, and the TPD measurement in the same manner as in Example 1. A peak was observed at around 1100 cm⁻¹ and around 3000 cm⁻¹ as a result of the FT-IR measurement. FIG. 2 shows the FT-IR measurement results, and FIG. 3 shows the temperature programmed desorption measurement results.

### Example 5

A thin film transistor was produced and evaluated in the same manner as in Example 1, except that the sputtering conditions and the annealing conditions of the channel layer were changed as shown in Table 1. The results are shown in Table 1.

A single-layer film was formed in the same manner as in Example 1, except that the sputtering conditions and the annealing conditions were changed as shown in Table 1, and subjected to the band gap measurement and the FT-IR measurement in the same manner as in Example 1. A peak was observed at around 1100 cm⁻¹ and around 3000 cm⁻¹ as a result of the FT-IR measurement.

### Example 6

A thin film transistor was produced and evaluated in the same manner as in Example 2, except that IGZO was used as the target, and the channel layer sputtering conditions were changed as shown in Table 1. The results are shown in Table 1.

A single-layer film was formed in the same manner as in Example 1, except that the target and the sputtering conditions were changed as shown in Table 1, and subjected to the band gap measurement and the FT-IR measurement in the same manner as in Example 1. A peak was observed at around 1100 cm⁻¹ and around 3000 cm⁻¹ as a result of the FT-IR measurement.

### Example 7

A thin film transistor was produced and evaluated in the same manner as in Example 2, except that IGZO was used as the target, and the channel layer sputtering conditions were changed as shown in Table 1. The results are shown in Table 1.

A single-layer film was formed in the same manner as in Example 1, except that the target and the sputtering conditions were changed as shown in Table 1, and subjected to the band gap measurement and the FT-IR measurement in the same manner as in Example 1. A peak was observed at around 1100 cm⁻¹ and around 3000 cm⁻¹ as a result of the FT-IR measurement.

### Example 8

A thin film transistor was produced and evaluated in the same manner as in Example 2, except that IGZO was used as the target, and the channel layer sputtering conditions were changed as shown in Table 1. The results are shown in Table 1.

A single-layer film was formed in the same manner as in Example 1, except that the target and the sputtering conditions were changed as shown in Table 1, and subjected to the band gap measurement and the FT-IR measurement in the same manner as in Example 1. A peak was observed at around 1100 cm⁻¹ and around 3000 cm⁻¹ as a result of the FT-IR measurement.

### Example 9

A thin film transistor was produced and evaluated in the same manner as in Example 1, except that the composition of the target and the channel layer sputtering conditions were changed as shown in Table 1. The results are shown in Table 1.

A single-layer film was formed in the same manner as in Example 1, except that the target and the sputtering conditions were changed as shown in Table 1, and subjected to the band gap measurement and the FT-IR measurement in the same manner as in Example 1. A peak was observed at around 1100 cm⁻¹ and around 3000 cm⁻¹ as a result of the FT-IR measurement.

### Example 10

A thin film transistor was produced and evaluated in the same manner as in Example 1, except that IGZO was used as the target, and the channel layer sputtering conditions were changed as shown in Table 1. The results are shown in Table 1.

A single-layer film was formed in the same manner as in Example 1, except that the target and the sputtering conditions were changed as shown in Table 1, and subjected to the band gap measurement and the FT-IR measurement in the same manner as in Example 1. A peak was observed at around 1100 cm⁻¹ and around 3000 cm⁻¹ as a result of the FT-IR measurement.

TABLE 1

| | | Example | | | | |
|---|---|---|---|---|---|---|
| | | 1 | 2 | 3 | 4 | 5 |
| Target | | ITZO | IGZO | ITZZO | ITZO | ITZO |
| Composition (atomic ratio) | | In:Sn:Zn = | In:Ga:Zn = | In:Sn:Zn:Zr = | In:Sn:Zn = | In:Sn:Zn = |
| | | 36.5:15:48.5 | 40:40:20 | 50:15:30:5 | 36.5:15:48.5 | 36.5:15:48.5 |
| Sputtering conditions | Ar | 19.4 | 19.4 | 19.4 | 15.2 | 18 |
| (sccm) | O₂ | — | — | — | 3.3 | 2 |
| | H₂O | 0.6 | 0.6 | 0.6 | — | — |
| | H₂ | — | — | — | 1.5 | — |

| Annealing | | 300° C., 1 h | 300° C., 1 h | 300° C., 1 h | 300° C., 1 h | 260° C., 1 MPa, 1 h |
|---|---|---|---|---|---|---|
| | | in air | in air | in air | in air | in water vapor |
| Source/drain | | Channel-etch | Lift-off | Channel-etch | Channel-etch | Channel-etch |
| Carrier concentration of thin film (cm⁻³) | | 4.3 × 10¹⁷ | 1.5 × 10¹⁷ | 2.6 × 10¹⁷ | 5.5 × 10¹⁷ | 8.0 × 10¹⁷ |
| Evaluation | W/L (μm) | 20/10 | 20/10 | 20/10 | 20/10 | 20/10 |
| of TFT | Mobility (cm²/Vs) | 18 | 2 | 10 | 21 | 25 |
| | OFF current (A) | 3.00 × 10⁻¹² | 7.00 × 10⁻¹² | 5.00 × 10⁻¹² | 1.00 × 10⁻¹² | 6.00 × 10⁻¹² |
| | ON current (A) | 1.00 × 10⁻⁴ | 3.00 × 10⁻⁶ | 7.00 × 10⁻⁴ | 1.00 × 10⁻³ | 3.00 × 10⁻⁴ |
| | Threshold voltage | 0 | 1.3 | 0.5 | −2 | −3 |
| | (Vth) | | | | | |
| | S-value (V/dec) | 0.4 | 1.3 | 0.5 | 0.7 | 0.8 |
| Evaluation | Band gap (eV) | 3.5 | 3.8 | 3.5 | 3.5 | 3.5 |
| of thin film | | | | | | |

| | | Example | | | | |
|---|---|---|---|---|---|---|
| | | 6 | 7 | 8 | 9 | 10 |
| Target | | IGZO | IGZO | IGZO | ITZO | IGZO |
| Composition (atomic ratio) | | In:Ga:Zn = | In:Ga:Zn = | In:Ga:Zn = | In:Sn:Zn = | In:Ga:Zn = |
| | | 60:20:20 | 50:30:20 | 60:30:10 | 20:20:60 | 50:10:40 |
| Sputtering conditions | Ar | 19.8 | 19.8 | 19.8 | 19.9 | 19.9 |
| (sccm) | O₂ | — | — | — | — | — |

| | | | | | |
|---|---|---|---|---|---|
| H₂O | 0.2 | 0.2 | 0.2 | 0.1 | 0.1 |
| H₂ | — | — | — | — | — |

| Annealing | | 300° C., 1 h | 300° C., 1 h | 300° C., 1 h | 300° C., 1 h | 300° C., 1 h |
|---|---|---|---|---|---|---|
| | | in air | in air | in air | in air | in air |
| Source/drain | | Lift-off | Lift-off | Lift-off | Channel-etch | Channel-etch |
| Carrier concentration of thin film (cm⁻³) | | 9.7 × 10¹⁷ | 2.3 ×10¹⁷ | 5.1 × 10¹⁷ | 5.8 × 10¹⁶ | 9.3 × 10¹⁷ |
| Evaluation | W/L (μm) | 20/10 | 20/10 | 20/10 | 20/10 | 20/10 |
| of TFT | Mobility (cm²/Vs) | 20 | 3 | 21 | 12 | 24 |
| | OFF current (A) | 3.00 × 10⁻¹² | 2.00 × 10⁻¹² | 5.00 × 10⁻¹² | 3.00 × 10⁻¹² | 1.00 × 10⁻¹² |
| | ON current (A) | 1.00 × 10⁻⁴ | 4.00 × 10⁻⁶ | 1.00 × 10⁻⁴ | 8.00 × 10⁻⁴ | 6.00 × 10⁻⁴ |
| | Threshold voltage | −0.5 | 1.5 | 0.2 | 1 | 0 |
| | (Vth) | | | | | |
| | S-value (V/dec) | 0.7 | 0.6 | 0.7 | 0.8 | 0.8 |
| Evaluation | Band gap (eV) | 3.7 | 3.8 | 3.7 | 3.6 | 3.5 |
| of thin film | | | | | | |

### Comparative Example 1

A thin film transistor was produced and evaluated in the same manner as in Example 1, except that the composition of the target and the channel layer sputtering conditions were changed as shown in Table 2. The results are shown in Table 2.

A single-layer film was formed in the same manner as in Example 1, except that the composition of the target and the sputtering conditions were changed as shown in Table 2, and subjected to the band gap measurement, the FT-IR measurement, and the TPD measurement in the same manner as in Example 1. A peak was not observed at around 1100 cm⁻¹ and around 3000 cm⁻¹ as a result of the FT-IR measurement. FIG. 2 shows the FT-IR measurement results, and FIG. 3 shows the temperature programmed desorption measurement results.

### Comparative Example 2

A thin film transistor was produced and evaluated in the same manner as in Example 2, except that the channel layer sputtering conditions were changed as shown in Table 2. The results are shown in Table 2.

A single-layer film was formed in the same manner as in Example 2, except that the sputtering conditions were changed as shown in Table 2, and subjected to the band gap measurement and the FT-IR measurement in the same manner as in Example 2. A peak was not observed at around 1100 cm⁻¹ and around 3000 cm⁻¹ as a result of the FT-IR measurement.

TABLE 2

| | | Comparative | Comparative |
|---|---|---|---|
| | | Example 1 | Example 2 |
| Target | | ITZO | IGZO |
| Composition (atomic ratio) | | In:Sn:Zn = | In:Ga:Zn = |
| | | 36.5:15:48.5 | 40:40:20 |
| Sputtering conditions | Ar | 16 | 19 |
| (sccm) | O₂ | 4 | 1 |
| | H₂O | — | — |
| | H₂ | — | — |

| Annealing | | 300° C., 1 h | 300° C., 1 h |
|---|---|---|---|
| | | in air | in air |
| S/D | | Channel-etch | Lift-off |
| Carrier concentration of thin film (cm⁻³) | | 5.8 × 10¹⁹ | 2.7 × 10¹⁹ |
| Evaluation | W/L (μm) | 20/10 | 20/10 |
| of TFT | Mobility (cm²/Vs) | — | — |
| | OFF current (A) | 3.00 × 10⁻³ | 7.00 × 10⁻⁵ |
| | ON current (A) | 2.00 × 10⁻³ | 1.00 × 10⁻⁵ |
| | Threshold voltage | — | — |
| | (Vth) | | |
| | S-value (V/dec) | — | — |
| Evaluation | Band gap (eV) | 3.3 | 3.8 |
| of thin film | | | |

### INDUSTRIAL APPLICABILITY

The thin film transistor according to the invention may be widely used as a unit electronic device of a semiconductor memory integrated circuit, a high-frequency signal amplifier device, a liquid crystal drive device, and the like.

Although only some exemplary embodiments and/or examples of the invention have been described in detail above, those skilled in the art will readily appreciate that many modifications are possible in the exemplary embodiments and/or examples without materially departing from the novel teachings and advantages of the invention. Accordingly, all such modifications are intended to be included within the scope of the invention.

The documents described in the specification are incorporated herein by reference in their entirety.

1. A semiconductor thin film comprising one or more amorphous metal oxides, an OH group being bonded to at least some of metal atoms of the one or more amorphous metal oxides.

2. The semiconductor thin film according to claim 1, comprising at least one or more metals selected from In and Zn.

3. The semiconductor thin film according to claim 2, comprising at least In.

4. The semiconductor thin film according to claim 2, comprising In and Zn.

5. The semiconductor thin film according to claim 2, comprising In, Zn, and a third element, the third element being at least one or more metal elements selected from Sn, Ga, Hf, Zr, Ti, Al, Mg, Ge, Sm, Nd, and La.

6. The semiconductor thin film according to claim 5, wherein the third element is Sn.

7. The semiconductor thin film according to claim 6, comprising In, Sn, and Zn at the following atomic ratios,
0.2<[In]/([In]+[Sn]+[Zn])<0.8
0<[Sn]/([In]+[Sn]+[Zn])<0.2
0.2<[Zn]/([In]+[Sn]+[Zn])<0.8
where, [In] is the number of indium atoms in the thin film, [Sn] is the number of tin atoms in the thin film, and [Zn] is the number of zinc atoms in the thin film.

8. The semiconductor thin film according to claim 5, wherein the third element is Ga.

9. The semiconductor thin film according to claim 8, comprising In, Ga, and Zn at the following atomic ratios,
0.5≦[In]/([In]+[Ga])<1
0.2≦[Zn]/([In]+[Ga]+[Zn])≦0.8
where, [In] is the number of indium atoms in the thin film, [Ga] is the number of gallium atoms in the thin film, and [Zn] is the number of zinc atoms in the thin film.

10. The semiconductor thin film according to claim 5, wherein the third element is Hf.

11. The semiconductor thin film according to claim 10, comprising In, Hf, and Zn at the following atomic ratios,
0.3<[In]/([In]+[Hf]+[Zn])<0.8
0.01<[Hf]/([In]+[Hf]+[Zn])<0.1
0.1<[Zn]/([In]+[Hf]+[Zn])<0.69
where, [In] is the number of indium atoms in the thin film, [Hf] is the number of hafnium atoms in the thin film, and [Zn] is the number of zinc atoms in the thin film.

12. The semiconductor thin film according to claim 5, wherein the third element is Zr.

13. The semiconductor thin film according to claim 12, comprising In, Zr, and Zn at the following atomic ratios,
0.3<[In]/([In]+[Zr]+[Zn])<0.8
0.01<[Zr]/([In]+[Zr]+[Zn])<0.1
0.1<[Zn]/([In]+[Zr]+[Zn])<0.69
where, [In] is the number of indium atoms in the thin film, [Zr] is the number of zirconium atoms in the thin film, and [Zn] is the number of zinc atoms in the thin film.

14. A method for producing a semiconductor thin film comprising any of the following steps (1a) to (1c):
(1a) sputtering a target comprising a metal oxide in a noble gas atmosphere containing water,
(1b) sputtering a target comprising a metal oxide in a gas atmosphere that comprises at least noble gas atoms, oxygen atoms, and hydrogen atoms, and
(1c) sputtering a target comprising a metal oxide to form a semiconductor thin film, and annealing the semiconductor thin film in a water vapor atmosphere.

15. A thin film transistor sequentially comprising:
a gate electrode;
a channel layer that comprises the semiconductor film according to claim 1; and
a protective film that comprises at least SiNₓ,
the protective film being adjacent to the channel layer.

16. A method for producing a thin film transistor comprising:
forming a channel layer by any of the following steps (1a) to (1c):
(1a) sputtering a target comprising a metal oxide in a noble gas atmosphere containing water,
(1b) sputtering a target comprising a metal oxide in a gas atmosphere that comprises at least noble gas atoms, oxygen atoms, and hydrogen atoms, and
(1c) sputtering a target comprising a metal oxide to form a channel layer, and annealing the channel layer in a water vapor atmosphere;
forming a conductor layer comprising at least one or more metals selected from the group consisting of Ti, Al, Mo, Cu, and Au, or an oxide thereof, so that the conductor layer is adjacent to the channel layer;
patterning the conductor layer to form a source electrode and a drain electrode; and
forming a protecting layer comprising SiNₓ on the source electrode, the drain electrode, and the channel layer.

17. The method for producing a thin film transistor according to claim 16, wherein the conductor layer comprises at least one or more metals selected from the group consisting of Ti, Al, Mo, Cu, and Au, and an oxide thereof.
